(19) United States
(12) Patent Application Publication
(10) Pub. No.: US 2026/0231769 A1
(43) Pub. Date: Aug. 6, 2026

(54) PANEL-LEVEL CHIP PACKAGE WITH SEAL RING STRUCTURE AND METHOD OF FORMING THE SAME

(71) Applicant: TAIWAN SEMICONDUCTOR MANUFACTURING COMPANY, LTD., Hsinchu (TW)

(72) Inventors: Yen-Liang LIN, Taichung City (TW); An-Jhih SU, Taoyuan City (TW)

(73) Assignee: TAIWAN SEMICONDUCTOR MANUFACTURING COMPANY, LTD., Hsinchu (TW)

(21) Appl. No.: 19/046,898

(22) Filed: Feb. 6, 2025

(51) Int. Cl. H01L 23/58; H01L 21/48; H01L 21/56; H01L 23/00; H01L 23/498; H01L 25/03

(52) U.S. Cl. CPC H10W 42/00; H10W 70/05; H10W 70/095; H10W 74/01; H10W 90/00; H10W 90/401; H10W 72/01235; H10W 72/01323; H10W 72/252; H10W 72/29; H10W 74/10; H10W 74/15; H10W 90/724; H10W 90/734

(57) ABSTRACT

A chip package structure includes a core substrate including a core material layer; an encapsulant embedded in the core material layer; an integrated circuit die embedded in the encapsulant; a first redistribution structure disposed above the core substrate; a second redistribution structure disposed below the core substrate; conductive features embedded in the core material layer and electrically connect the first and second redistribution structures; a seal ring structure disposed in the peripheral regions of the core substrate, first redistribution structure and second redistribution structure, wherein the seal ring structure includes a stack of metal pattern layers and vias and is electrically isolated from the conductive layers within the first and second redistribution structures and the conductive features within the core substrate; and conductive connectors attached to the second redistribution structure.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As demand for more compact electronic devices has grown, a need for smaller and more creative packaging techniques for semiconductor dies has emerged.

Panel-level packaging (PLP) is one of the latest packaging trends in semiconductor electronics. In addition to the development of heterogeneous integration technologies, including multi-die packaging, passive device integration in package and redistribution layer or package-on-package approaches, larger substrate formats are also targeted. Compared with wafer-level packaging technologies, panel-level packaging technologies utilize rectangular panel-like substrates to improve area utilization, enhance production efficiency, and reduce manufacturing costs. However, there are many challenges with current panel-level packaging technologies.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A to 1N illustrate cross-sectional views of various stages in the formation of a chip package, in accordance with some embodiments.

FIG. 2 illustrates a plan view (e.g., bottom-up view) of the chip package shown in FIG. 1N, in accordance with some embodiments.

FIG. 3 illustrates a cross-sectional view of a chip package, in accordance with some embodiments.

FIG. 4 illustrates a cross-sectional view of a chip package, in accordance with some embodiments.

FIG. 5 illustrates a cross-sectional view of a chip package, in accordance with some embodiments.

FIG. 6 illustrates a cross-sectional view of a chip package, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The structure may be otherwise oriented (rotated 90 degrees or at other orientations) and the spatially relative descriptors used herein may likewise be interpreted accordingly.

A (panel-level) chip package and a method of forming the same are provided in accordance with various embodiments. The chip package includes a seal ring structure disposed at the edge of the package (e.g., disposed in the peripheral regions of the core substrate and the redistribution structures on both sides thereof) and electrically isolated from the internal conductive features, which is composed of a stack of metal pattern/pad layers and metal vias. The seal ring structure can protect the IC dies and conductive features with the package during the singulation process and/or prevent moisture from penetrating into the internal function region of the package. Accordingly, the reliability of the package structure is improved.

The embodiments discussed herein provide examples to enable making or using the subject matter of this disclosure, and a person having ordinary skill in the art will readily understand that modifications can be made while remaining within the contemplated scope of different embodiments. Throughout the various views and illustrative embodiments, like reference numbers are used to designate like elements. Although method embodiments may be discussed as being performed in a particular order, other method embodiments may be performed in any logical order.

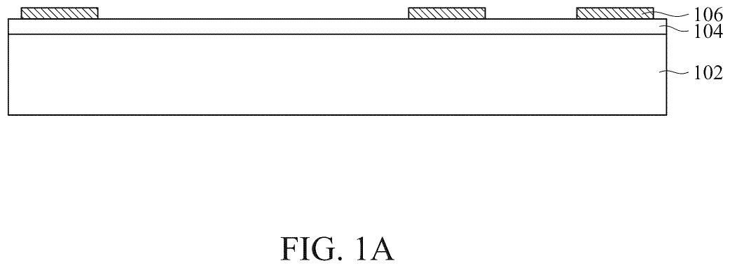

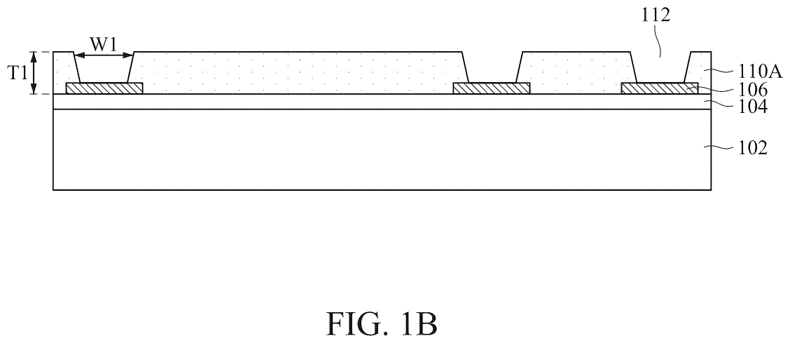

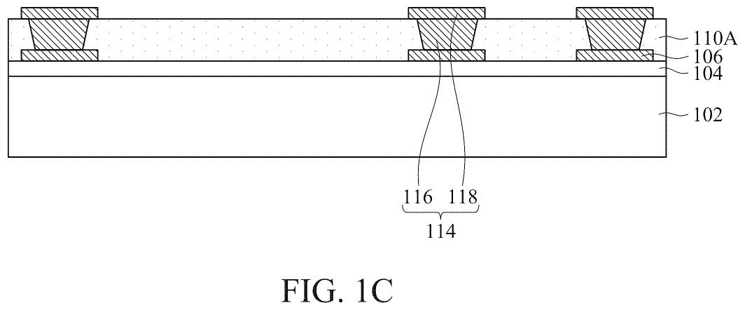

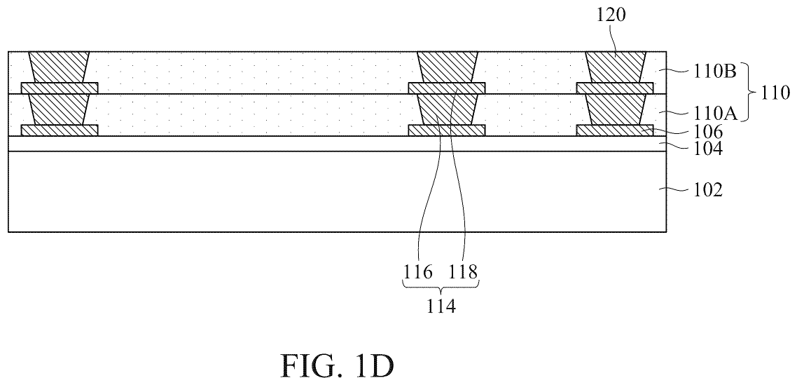

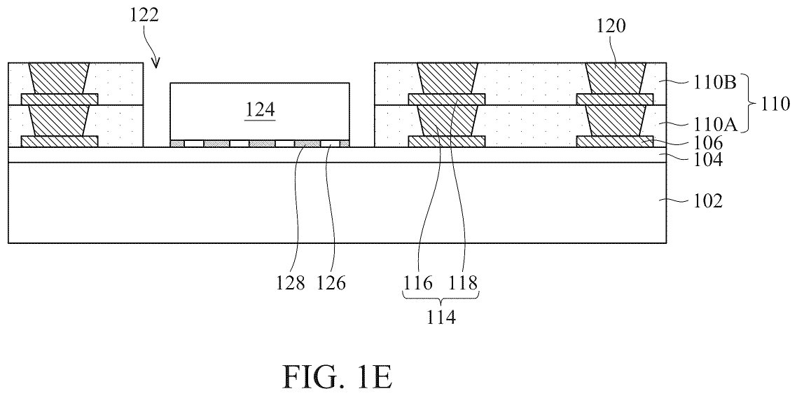

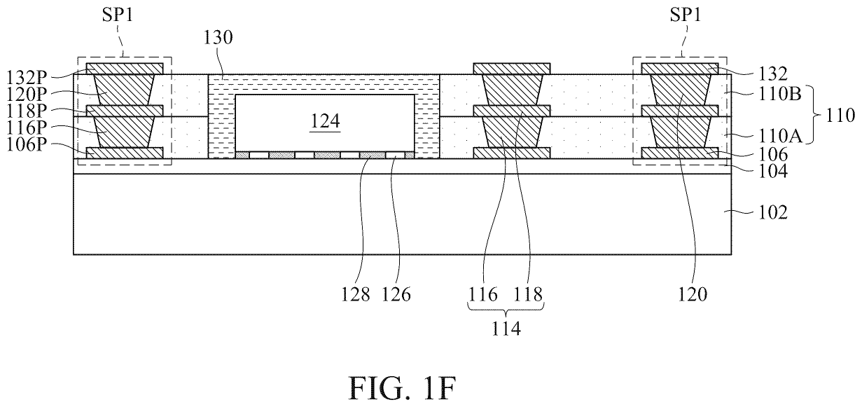

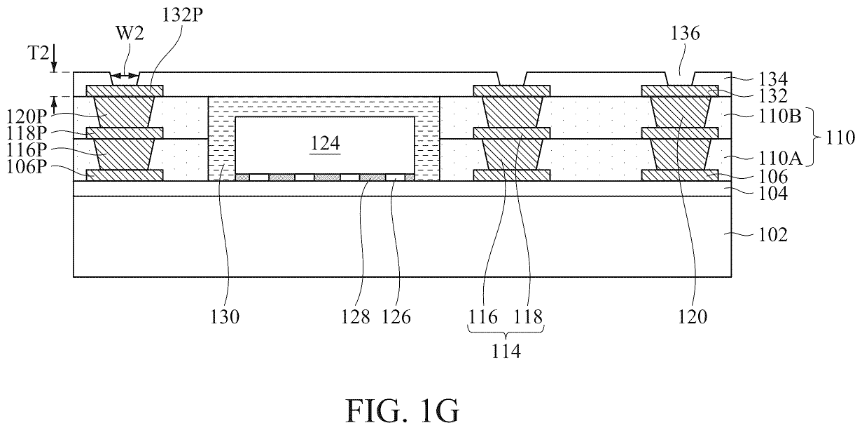

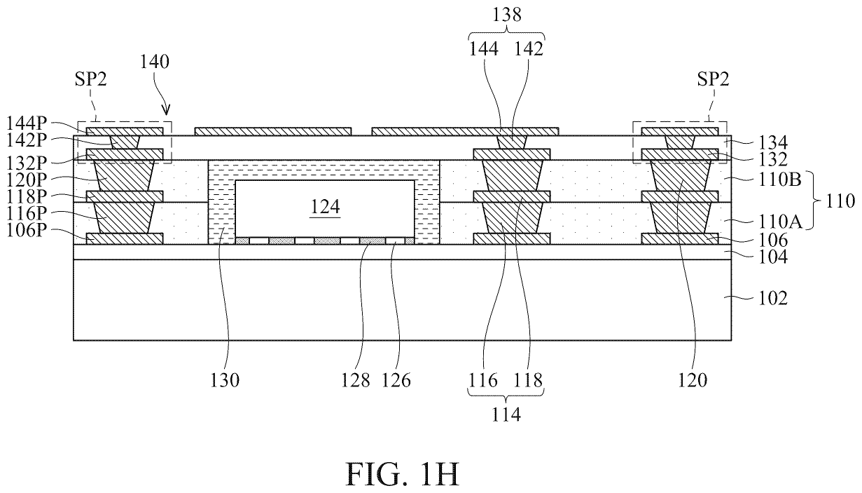

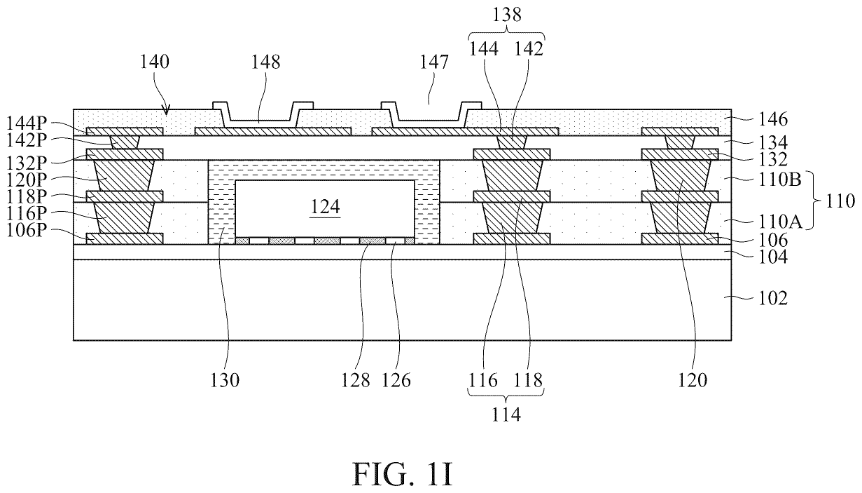

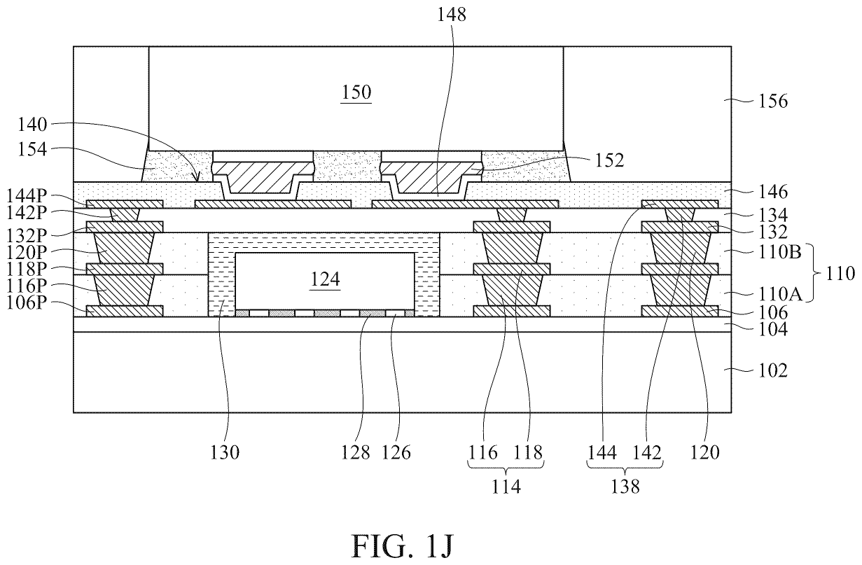

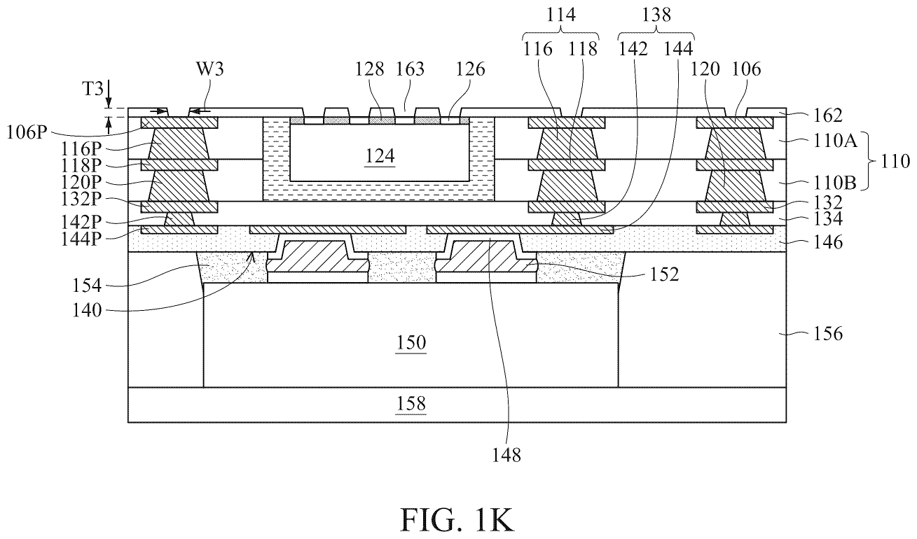

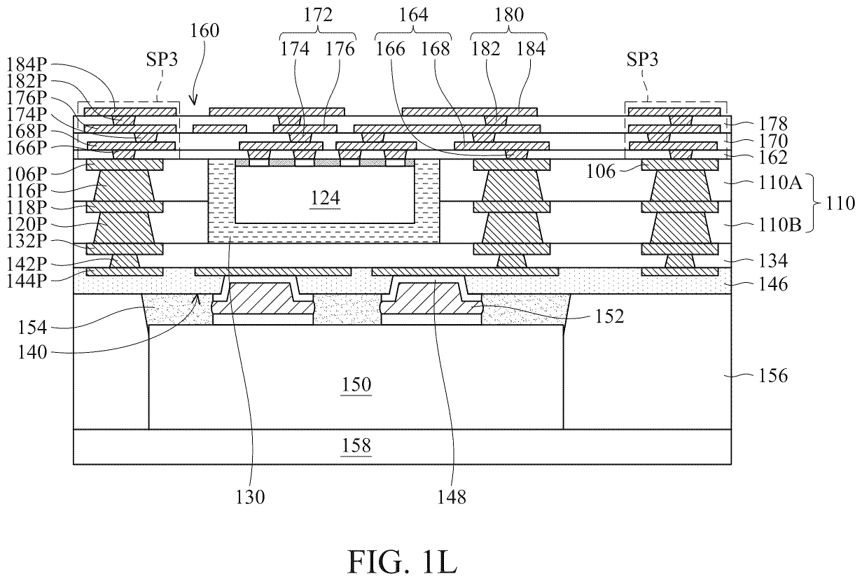

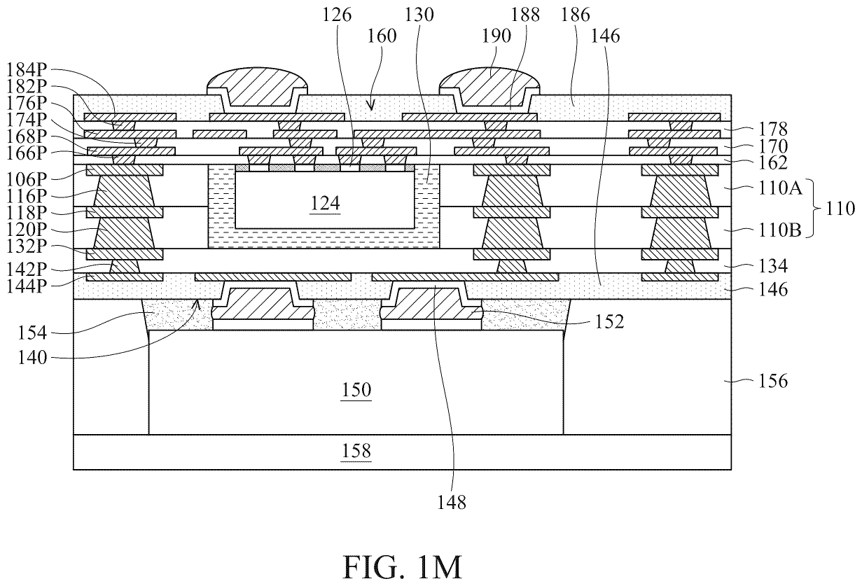

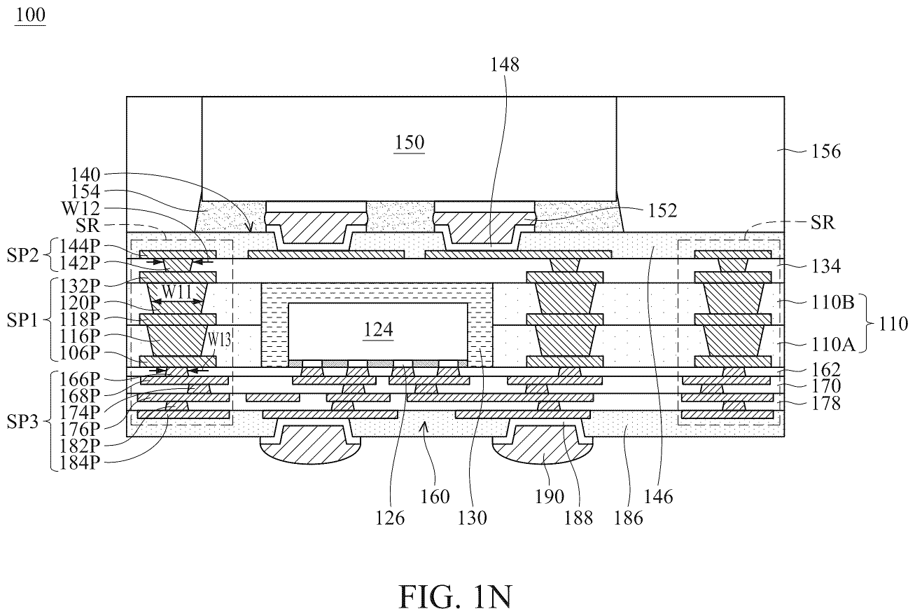

FIGS. 1A to 1N illustrate cross-sectional views of various stages in the formation of a chip package 100 (see e.g., FIG. 1N), in accordance with some embodiments. The chip package 100 is formed by constructing a panel-level chip package structure in which multiple integrated circuit (IC) dies are bonded to a panel-level redistribution layer (RDL) structure. The panel-level chip package structure is then diced into individual chip packages, wherein each individual chip package includes one or more IC dies that are connected to a discrete redistribution layer structure that includes a portion of the initial panel-level redistribution layer structure (therefore, the chip package 100 is also referred to as a panel-level chip package herein). The panel-level RDL structures can be formed to include fan-out or fan-in RDL structures as desired for each of the IC dies, in some cases.

In FIG. 1A, a carrier substrate 102 is provided, and a release layer 104 is formed on the carrier substrate 102, in accordance with some embodiments. The carrier substrate 102 may be a glass carrier substrate, a ceramic carrier substrate, or the like. In some embodiments, the carrier substrate 102 is a rectangular panel with a larger surface area than that of a round semiconductor wafer (e.g., greater than 300 mm×300 mm²). A larger carrier allows more packages (e.g., chip packages 100) to be formed simultaneously on the carrier substrate 102, thereby improving area utilization, increasing production efficiency, and reducing manufacturing costs. It should be understood that, for the sake of simplicity, only the formation of one of the chip packages 100 is shown in the figures described below (e.g., FIGS. 1A to 1N).

The release layer 104 may be formed of a polymer-based material, which may be removed together with the carrier substrate 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV light. The release layer 104 may be dispensed as a liquid and then cured, or it may be a laminate film laminated onto the carrier substrate 102, or the like. The top surface of the release layer 104 may be flat.

FIG. 1A also illustrates that a first conductive pattern 106 is formed on the release layer 104 in accordance with some embodiments. The first conductive pattern 106 may include both metal pads and metal traces (not shown for simplicity) for routing electrical signals, power, and/or ground lines, although in some embodiments the first conductive pattern 106 may only include metal pads. In some embodiments, the metal pads of the first conductive pattern 106 have a circular cross-sectional shape in a plan view, although other cross-sectional shapes may be used.

The formation process of the first conductive pattern 106 may include forming a seed layer (not shown) on the release layer 104; forming a patterned mask (not shown) such as a photoresist on the seed layer, and then performing a plating process on the exposed seed layer to plate a conductive material. The patterned mask and the portions of the seed layer covered by the patterned mask are then removed, leaving the first conductive pattern 106 as shown in FIG. 1A. The seed layer is a metal layer, which may be a single layer or a composite layer including a plurality of sub-layers formed of different materials. In some embodiments, the seed layer includes a titanium layer and a copper layer on the titanium layer. The seed layer may be formed using, for example, a physical vapor deposition (PVD) process or the like. The plating may be performed using, for example, an electrochemical plating process. The plated conductive material may include a metal material such as copper, tungsten, aluminum, an alloy thereof, a combination thereof, or the like. The patterned mask may be removed by an acceptable ashing or stripping process, such as using oxygen plasma or the like. Then, the exposed portions of the seed layer are removed by an acceptable etching process, such as by wet or dry etching.

In FIG. 1B, a first core material layer 110A is formed on the first conductive pattern 106 and the release layer 104, in accordance with some embodiments. As will be discussed in greater detail below, the first core material layer 110A is a part of a core substrate 110 (see e.g., FIG. 1D) of the chip package 100. The first core material layer 110A may be formed from a pre-impregnated composite fiber (“prepreg”), a build-up insulating film, paper, glass fiber, non-woven glass fabric, silicon, or the like. In some embodiments, the first core material layer 110A is formed from a prepreg including glass fiber and a resin. In some embodiments, the first core material layer 110A is an epoxy-impregnated glass-cloth laminate, a polyimide-impregnated glass-cloth laminate, or the like.

As an example to form the first core material layer 110A, the material of the first core material layer 110A in a liquid or semi-liquid form is disposed on the first conductive pattern 106 and the release layer 104 and then cured by a thermal lamination process. The thermal lamination process may include applying a pressure of 0.6 PSI to 10 PSI to the material of the first core material layer 110A with a temperature of 25° C. to 90° C. After the thermal lamination process, the first conductive pattern 106 is embedded in the first core material layer 110A and may have a bottom surface that is coplanar with the bottom surface of the first core material layer 110A. The first core material layer 110A may have a thickness T1 between about 10 μm and about 60 μm, such as about 50 μm, although other thickness values and ranges are contemplated and may be used.

Afterwards, openings 112 are formed through the first core material layer 110A and expose the metal pads of the first conductive pattern 106. The openings 112 may be formed by laser drilling. Other processes, such as mechanical drilling with a drill bit, may also be used to form the openings 112. In some embodiments, the openings 112 may have inclined sidewalls, and the width W1 of the openings 112 gradually decreases toward the first conductive pattern 106. The width W1 of the openings 112 may be in a range from about 50 μm to about 200 μm, such as 70 μm, although other width values or ranges are contemplated and may be used. In other embodiments, the openings 112 may have vertical sidewalls and a uniform width. In some embodiments, the openings 112 have a circular cross-sectional shape in a plan view, although other cross-sectional shapes may be used. A cleaning process may then be performed to clean areas near the openings 112 which may have been smeared with removed material of the first core material layer 110A.

In FIG. 1C, a conductive layer 114 is formed in the openings 112 and on the top surface of the first core material layer 110A, in accordance with some embodiments. The conductive layer 114 may include first conductive vias 116 and a second conductive pattern 118 formed on the first core material layer 110A and the first conductive vias 116. The first conductive vias 116 are formed in the openings 112 and in physical contact with the metal pads of the first conductive pattern 106. Since the openings 112 may have inclined sidewalls, the first conductive vias 116 also have inclined sidewalls. The second conductive pattern 118 may include both metal pads and metal traces (not shown for simplicity) for routing electrical signals, power, and/or ground lines, although in some embodiments the second conductive pattern 118 may only include metal pads. In some embodiments, the metal pads of the second conductive pattern 118 have a circular cross-sectional shape in a plan view, although other cross-sectional shapes may be used.

The formation process of the conductive layer 114 may include forming a seed layer (not shown) in the openings 112 and on the top surface of the first core material layer 110A; forming a patterned mask (not shown) such as a photoresist on the seed layer, and then performing a metal plating process on the exposed seed layer to plate a metallic material. The patterned mask and the portions of the seed layer covered by the patterned mask are then removed, leaving the conductive layer 114 as shown in FIG. 1C. The seed layer is a metal layer, which may be a single layer or a composite layer including a plurality of sub-layers formed of different materials. In some embodiments, the seed layer includes a titanium layer and a copper layer on the titanium layer. The seed layer may be formed using, for example, a physical vapor deposition (PVD) process or the like. The plating may be performed using, for example, an electrochemical plating process. The plated conductive material may include a metal material such as copper, tungsten, aluminum, an alloy thereof, a combination thereof, or the like. The patterned mask may be removed by an acceptable ashing or stripping process, such as using oxygen plasma or the like. Then, the exposed portions of the seed layer are removed by an acceptable etching process, such as by wet or dry etching.

In FIG. 1D, a second core material layer 110B is formed on the first core material layer 110A and the conductive layer 114, in accordance with some embodiments. The second core material layer 110B may be the same material as the first core material layer 110A and formed using the same or similar processes. In other embodiments, the second core material layer 110B has a different material than the material of the first core material layer 110A. As an example to form the second core material layer 110B, the material of the second core material layer 110B in a liquid or semi-liquid form is disposed on the first core material layer 110A and the conductive layer 114 and then cured by a thermal lamination process. In some embodiments, the thickness of the second core material layer 110B is the same as or similar to the thickness of the first core material layer 110A, although other thicknesses are contemplated and may be used. In some embodiments, the second conductive pattern 118 is embedded in the second core material layer 110B and has a bottom surface that is coplanar with the bottom surface of the second core material layer 110B.

FIG. 1D also illustrates that second conductive vias 120 are formed (e.g., embedded) in the second core material layer 110B and in physical contact with the metal pads of the second conductive pattern 118 in accordance with some embodiments. Before forming the second conductive vias 120, openings (not shown) are formed through the second core material layer 110B and expose the metal pads of the second conductive pattern 118. The structure, size, and formation method of the openings may be similar to those of the openings 112 described above, and thus are not repeated here. Afterwards, the second conductive vias 120 are formed in the openings. Since the openings may have inclined sidewalls, the second conductive vias 120 also have inclined sidewalls, although the present disclosure is not limited thereto.

The formation process of the second conductive vias 120 may include forming a seed layer (not shown) in the openings and on the top surface of the second core material layer 110B; forming a patterned mask (not shown) such as a photoresist on the seed layer; and then performing a metal plating process on the exposed seed layer to plate a metallic material. The patterned mask and the portions of the seed layer covered by the patterned mask are then removed, leaving the second conductive vias 120 as shown in FIG. 1D. The seed layer is a metal layer, which may be a single layer or a composite layer including a plurality of sub-layers formed of different materials. In some embodiments, the seed layer includes a titanium layer and a copper layer on the titanium layer. The seed layer may be formed using, for example, a physical vapor deposition (PVD) process or the like. The plating may be performed using, for example, an electrochemical plating process. The plated conductive material may include a metal material such as copper, tungsten, aluminum, an alloy thereof, a combination thereof, or the like. The patterned mask may be removed by an acceptable ashing or stripping process, such as using oxygen plasma or the like. Then, the exposed portions of the seed layer are removed by an acceptable etching process, such as by wet or dry etching. In some embodiments, a planarization process (e.g., a chemical mechanical polishing (CMP) process or a mechanical grinding process) may be performed to remove the excess conductive material on the second core material layer 110B.

It should be understood that the first core material layer 110A and the second core material layer 110B may form (and be collectively referred to as) a core substrate 110 of the chip package 100, where dies and redistribution structures may be disposed on the core substrate 110 (which will be described below). Compared with wafer-level chip packaging, panel-level chip packaging requires such a core substrate 110 to increase structural strength of the package due to its larger unit size. Although the core substrate 110 in this embodiment includes two core material layers (110A and 110B), more or fewer core material layers may be used depending on the thickness of the embedded first die 124 (e.g., see FIG. 1E). Similarly, the number of layers of conductive patterns and vias embedded in the core material layers can also be changed accordingly. In the case of using one core material layer as the core substrate, the conductive vias passing through it may also be referred to as plated through hole (PTH) vias.

In FIG. 1E, a cavity 122 is formed through the core substrate 110 and expose the release layer 104, in accordance with some embodiments. The cavity 122 may be formed by a laser drill process, although other drilling processes such as a mechanical drill process may be used. In some embodiments, the cavity 122 has a rectangular cross-sectional shape in a plan view, although other cross-sectional shapes may be used. The sidewalls of the cavity 122 may be perpendicular to the bottom surface of the core substrate 110 (or the first core material layer 110A), although sidewalls of the cavity 122 may also be inclined relative to the bottom surface of the core substrate 110.

FIG. 1E also illustrates that a first die 124 is disposed in the cavity 122 and on the release layer 104, in accordance with some embodiments. The first die 124 may be a passive device such as an integrated passive device (IPD), although other types of IC dies may be used. The first die 124 may include bond pads (not shown) such as aluminum pads to which external connections are made. The bond pads may be disposed on an active side of the first die 124. The first die 124 may also include die connectors 126. The die connectors 126 may be metal pillars that are physically and electrically formed on respective ones of the bond pads and electrically couple the internal passive features or circuitry of the first die 124. In some embodiments, the material of the die connectors 126 includes copper and is formed by, for example, electroplating. The first die 124 may also include a passivation film 128 that laterally encapsulates the die connectors 126. The passivation film 128 may include polyimide, polybenzoxazole (PBO), benzocyclobutene (BCB), a combination thereof, or the like. In other embodiments, the passivation film 128 may be omitted.

In some embodiments, an adhesive film (not shown) is disposed on the active side of the first die 124 and adheres the first die 124 (e.g., the die connectors 126 and the passivation film 128 (if present)) to the release layer 104. The adhesive film may be any suitable insulating adhesive, epoxy, die attach film (DAF), or the like. Although FIG. 1E illustrates one first die 124, in other embodiments, more first dies 124 may be disposed in the cavity 22.

In FIG. 1F, an encapsulant 130 is formed (e.g., filled) in the cavity 122 and buries the first die 124, in accordance with some embodiments. As such, the encapsulant 130 is embedded in the core substrate 110 and disposed on the release layer 104. The first die 124, including the die connectors 126, is disposed on the release layer 104 and embedded in the encapsulant 130. The encapsulant 130 may be a molding compound, epoxy, or the like. The encapsulant 130 may be applied by compression molding, transfer molding, or the like. In some embodiments, a planarization process (e.g., a chemical mechanical polishing (CMP) process or a mechanical grinding process) may be performed to remove the excess materials of the encapsulant 130 on the top surface of the second core material layer 110B until the top surfaces of the encapsulant 130, the second core material layer 110B and the second conductive vias 120 are substantially coplanar.

A third conductive pattern 132 is then formed on the second core material layer 110B and in physical contact with the second conductive vias 120, in accordance with some embodiments. The third conductive pattern 132 may include both metal pads and metal traces (not shown for simplicity) for routing electrical signals, power, and/or ground lines, although in some embodiments the third conductive pattern 132 may only include metal pads. In some embodiments, the metal pads of the third conductive pattern 132 have a circular cross-sectional shape in a plan view, although other cross-sectional shapes may be used. The material and formation method of the third conductive pattern 132 may be similar to those of the first conductive pattern 106 described above, and thus are not repeated here.

It should be noted that FIGS. 1A to 1F also illustrate the formation of metal patterns (or pads) 106P, 118P, 132P and metal vias 116P, 120P in and/or on the core substrate 110 and adjacent the edge of the package (e.g., within the dashed box shown in FIG. 1F) in accordance with some embodiments. In some embodiments, the metal patterns 106P, 118P, 132P and metal vias 116P, 120P adjacent the edge of the package are formed using the same processes and materials used to form the corresponding conductive patterns 106, 118, 132 and conductive vias 116, 120 located in the internal functional area of the package (e.g., those shown in the center of the figures and adjacent the first die 124 and encapsulant 130). For example, the metal patterns 106P, 118P, 132P and metal vias 116P, 120P may be formed simultaneously with the corresponding conductive patterns 106, 118, 132 and conductive vias 116, 120 (the term “corresponding” as used here means that these components are located on the same level). In some embodiments, the metal patterns 106P, 118P, 132P and metal vias 116P, 120P are electrically isolated from the corresponding conductive patterns 106, 118, 132 and conductive vias 116, 120. In some embodiments, the metal patterns 106P, 118P, 132P and metal vias 116P, 120P extend from the top surface of the core substrate 110 to the bottom surface of the core substrate 110, and are arranged along the entire edge of the package in a plan view. As will be discussed in greater detail below, the metal patterns 106P, 118P, 132P and metal vias 116P, 120P may form (and be collectively referred to) as a first seal ring part SP1, which is a part of a seal ring SR of the chip package 100 (see e.g., FIG. 1N).

Referring next FIGS. 1G to 1H, which illustrate the formation of a first redistribution structure 140 (may also be referred to as a top redistribution structure 140) on the top surface of the core substrate 110, in accordance with some embodiments. The first redistribution structure 140 may include a dielectric layer 134 and a conductive layer 138 formed in the dielectric layer 134. The conductive layer 138 may include conductive lines, conductive vias, conductive pads, or other conductive features, and may be considered redistribution layers or interconnects in some cases. The first redistribution structure 140 described herein is merely an example, and may have a different numbers, arrangements, or configurations of dielectric layers or conductive layers in other embodiments. For example, if more dielectric layers and conductive layers are to be formed, some steps and processes discussed below may be repeated.

In FIG. 1G, a dielectric layer 134 is formed on the core substrate 110 (e.g., the second core material layer 110B), the encapsulant 130, and the third conductive pattern 132 (and the metal pattern 132P), in accordance with some embodiments. In some embodiments, the dielectric layer 134 is formed of a polymer, which may be a photosensitive material such as polybenzoxazole (PBO), polyimide, benzocyclobutene (BCB), or the like. In other embodiments, the dielectric layer 134 is formed of a nitride such as silicon nitride; an oxide such as silicon oxide, phosphosilicate glass (PSG), borosilicate glass (BSG), boron-doped phosphosilicate glass (BPSG), or the like; or the like. The dielectric layer 134 may be formed by any acceptable deposition process, such as spin coating, chemical vapor deposition (CVD), laminating, the like, or a combination thereof. The dielectric layer 134 may have a thickness T2 between about 10 μm and about 30 μm, such as about 25 μm, although other thickness values and ranges are contemplated and may be used. In some embodiments, the third conductive pattern 132 (and the metal pattern 132P) is embedded in the dielectric layer 134 and has a bottom surface that is coplanar with the bottom surface of the dielectric layer 134.

FIG. 1G also illustrates that the dielectric layer 134 is patterned to form openings 136 exposing the metal pads of the third conductive pattern 132 in accordance with some embodiments. The dielectric layer 134 may be patterned using an acceptable photolithographic process. For example, in embodiments where the dielectric layer 134 is a photo-sensitive material, the dielectric layer 134 may be exposed to light using a lithography mask. The dielectric layer 134 may then be developed to form the openings 136 after the exposure. In other embodiments, a photoresist may be formed and patterned over the dielectric layer 134, and then the dielectric layer 134 may be etched using the patterned photoresist as an etching mask. In some embodiments, the openings 136 may have inclined sidewalls, and the width W2 of the openings 136 gradually decreases toward the third conductive pattern 132 (and the metal pattern 132P). The width W2 of the openings 136 may be in a range from about 10 μm to about 50 μm, such as about 30 μm, although other width values or ranges are contemplated and may be used. In other embodiments, the openings 136 may have vertical sidewalls and a uniform width. In some embodiments, the openings 136 have a circular cross-sectional shape in a plan view, although other cross-sectional shapes may be used.

In FIG. 1H, a conductive layer 138 is formed in the openings 136 and on the top surface of the dielectric layer 134, in accordance with some embodiments. The conductive layer 138 may include conductive vias 142 and a conductive pattern 144 formed on the dielectric layer 134 and the conductive vias 142. The conductive vias 142 are formed in the openings 136 and in physical contact with the metal pads of the third conductive pattern 132. Since the openings 136 may have inclined sidewalls, the conductive vias 142 also have inclined sidewalls. The conductive pattern 144 may include both metal pads and metal traces for routing electrical signals, power, and/or ground lines, although in some embodiments the conductive pattern 144 may only include metal pads. In some embodiments, the metal pads of the conductive pattern 144 have a circular cross-sectional shape in a plan view, although other cross-sectional shapes may be used. The material and formation method of the conductive layer 138 may be similar to those of the conductive layer 114 described above, and thus are not repeated here.

It should be noted that FIGS. 1G to 1H also illustrate the formation of a metal pattern (or pad) 144P and a metal via 142P in and/or on the first redistribution structure 140 and adjacent the edge of the package (e.g., within the dashed box shown in FIG. 1H) in accordance with some embodiments. In some embodiments, the metal pattern 144P and metal via 142P adjacent the edge of the package are formed using the same processes and materials used to form the corresponding conductive pattern 144 and conductive vias 142 located in the internal functional area of the package (e.g., those shown in the center of the figures and adjacent and/or over the first die 124 and encapsulant 130). For example, the metal pattern 144P and metal via 142P may be formed simultaneously with the corresponding conductive pattern 144 and conductive vias 142 (the term “corresponding” as used here means that these components are located on the same level). In some embodiments, the metal pattern 144P and metal via 142P are electrically isolated from the corresponding conductive pattern 144 and conductive vias 142. In some embodiments, the metal pattern 144P and metal via 142P extend from the top surface of the dielectric layer 134 to the bottom surface of the dielectric layer 134 (to contact the top surface of the metal pattern 132P), and are arranged along the entire edge of the package in a plan view. As will be discussed in greater detail below, the metal pattern 144P and metal via 142P may form (and be collectively referred to as) a second seal ring part SP2, which is also a part of a seal ring SR of the chip package 100 (see e.g., FIG. 1N).

In FIG. 1I, a solder resist layer 146 is formed on the dielectric layer 134 and the conductive pattern 144 (and the metal pattern 144P), in accordance with some embodiments. The solder resist layer 146 may include a suitable insulating material, such as a dielectric material, a polymer material, or the like, and may be formed using any suitable deposition technique.

FIG. 1I also illustrates that the formation of under-bump metallurgies (UBMs) 148 in and on the solder resist layer 146 in accordance with some embodiments. The formation process of the UBMs 148 may include forming openings 147 in the solder resist layer 146 to expose portions of the conductive pattern 144; forming a seed layer (not shown) in the openings 147 and on the top surface of the solder resist layer 146; forming a patterned mask (not shown) such as a photoresist on the seed layer; and then performing a metal plating process on the exposed seed layer to plate a metallic material. The patterned mask and the portions of the seed layer covered by the patterned mask are then removed, leaving the UBMs 148 as shown in FIG. 1I. In some embodiments, the openings 147 may be formed using suitable photolithography and etching techniques. The etching techniques may include a dry etching process or a wet etching process, and may be anisotropic. In some embodiments, the seed layer includes a titanium layer and a copper layer on the titanium layer. The seed layer may be formed using, for example, a physical vapor deposition (PVD) process or the like. The plating may be performed using, for example, an electrochemical plating process. The plated conductive material may include a metal material such as copper, tungsten, aluminum, an alloy thereof, a combination thereof, or the like. The patterned mask may be removed by an acceptable ashing or stripping process, such as using oxygen plasma or the like. Then, the exposed portions of the seed layer are removed by an acceptable etching process, such as by wet or dry etching. In some embodiments, the metal pattern 144P remains buried within the solder resist layer 146 (i.e., not exposed) after the UBMs 148 are formed.

In FIG. 1J, a second die 150 is attached to the first redistribution structure 140, in accordance with some embodiments. The second die 150 may be an IC die. For example, the second die 150 may be a logic die (e.g., central processing unit (CPU) die, graphics processing unit (GPU) die, system-on-a-chip (SoC) die, microcontroller, or the like), a memory die (e.g., dynamic random access memory (DRAM) die, static random access memory (SRAM) die, hybrid memory cube (HMC) module, a high bandwidth memory (HBM) module, or the like), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof. Although FIG. 1J illustrates one second die 150, in other embodiments, more second dies 150 may be attached to the first redistribution structure 140. In some embodiments, the second die 150 is disposed at a position overlapping the first die 124 in a plan view, which may reduce the signal transmitting routes between the first die 124 and the second die 150 for improved performance.

In some embodiments, the second die 150 is attached to the first redistribution structure 140 using solder regions, which may be formed on the UBMs 148 exposed through the solder resist layer 146 and/or the die connectors (not specifically marked) of the second die 150. After placing the second die 150 over the first redistribution structure 140, the solder regions are in physical contact with respective UBMs 148 on the first redistribution structure 140 and respective die connectors of the second die 150. A reflow process is then performed on the solder region to melt and merge the solder regions into solder joints 152. The solder joints 152 electrically and mechanically couple the second die 150 to the first redistribution structure 140. Other conductive connectors may be used to electrically connect the second die 150 to the first redistribution structure 140.

In some embodiments, an underfill 154 is formed between the second die 150 and the first redistribution structure 140 (or the solder resist layer 146) and surrounds the solder joints 152 beneath the second die 150. The underfill 154 may protect the solder joints 152 and enhance the connection between the second die 150 and the first redistribution structure 140. The underfill 154 may be made of or include an insulating material such as an underfill material. The underfill material may include an epoxy, a resin, a filler material, a stress release agent (SRA), an adhesion promoter, another suitable material, or a combination thereof. The underfill 154 may be formed by a capillary flow process after the second die 150 is attached to the first redistribution structure 140. In other embodiments, the underfill 154 may be omitted.

FIG. 1J also illustrates that an encapsulant 156 is formed over the first redistribution structure 140 and buries the second die 150 and the underfill 154 (if present) in accordance with some embodiments. The encapsulant 156 may be a molding compound, epoxy, or the like. The encapsulant 156 may be applied by compression molding, transfer molding, or the like. In some embodiments, a planarization process (e.g., a chemical mechanical polishing (CMP) process or a mechanical grinding process) may be performed to remove the excess materials of the encapsulant 156 on the second die 150 until the top surfaces of the second die 150 and the encapsulant 156 are substantially coplanar. In some embodiments, if the second die 150 is already exposed from the encapsulant 156, the planarization process may be omitted.

In FIG. 1K, a de-bonding process is performed to detach (or “de-bond”) the carrier substrate 102 from the core substrate 110, in accordance with some embodiments. The de-bonding process may include projecting a light, such as a laser light or an UV light, onto the release layer 104 so that the release layer 104 decomposes under the heat of the light and the carrier substrate 102 may be removed. The remaining structure is then flipped upside-down and bonded to another carrier substrate 158, in accordance with some embodiments. The carrier substrate 158 may be similar to the carrier substrate 102, in some cases. The structure may be attached to the carrier substrate 158 using an adhesive, a release layer, or the like (not shown).

FIG. 1K also illustrates the beginning of formation of a second redistribution structure 160 (may also be referred to as a bottom redistribution structure 160, see e.g., FIG. 1L) on the bottom surface of the core substrate 110 that is originally covered by the carrier substrate 102, in accordance with some embodiments. For example, a dielectric layer 162 is formed on the core substrate 110 (e.g., the first core material layer 110A), the encapsulant 130, the first die 124 (including the die connectors 126), and the first conductive pattern 106 (and the metal pattern 106P). In some embodiments, the dielectric layer 162 is formed of a polymer, which may be a photo-sensitive material such as polybenzoxazole (PBO), polyimide, benzocyclobutene (BCB), or the like. In other embodiments, the dielectric layer 162 is formed of a nitride such as silicon nitride; an oxide such as silicon oxide, phosphosilicate glass (PSG), borosilicate glass (BSG), boron-doped phosphosilicate glass (BPSG), or the like; or the like. The dielectric layer 162 may be formed by any acceptable deposition process, such as spin coating, chemical vapor deposition (CVD), laminating, the like, or a combination thereof. The dielectric layer 162 may have a thickness T3 between about 10 μm and about 30 μm, such as about 20 μm, although other thickness values and ranges are contemplated and may be used.

The dielectric layer 162 is then patterned to form openings 163 exposing the metal pads of the first conductive pattern 106 (and the metal pattern 106P) and the die connectors 126 of the first die 124 in accordance with some embodiments. The dielectric layer 162 may be patterned using an acceptable photolithographic process. For example, in embodiments where the dielectric layer 162 is a photo-sensitive material, the dielectric layer 162 may be exposed to light using a lithography mask. The dielectric layer 162 may then be developed to form the openings 136 after the exposure. In other embodiments, a photoresist may be formed and patterned over the dielectric layer 162, and then the dielectric layer 162 may be etched using the patterned photoresist as an etching mask. The etching process may also remove a portion of the adhesive film (not shown) on the active side of the first die 124 to expose the die connectors 126. In some embodiments, the openings 163 may have inclined sidewalls, and the width W3 of the openings 163 gradually decreases toward the first conductive pattern 106 (and the metal pattern 106P) and the die connectors 126. The width W3 of the openings 163 may be in a range from about 10 μm to about 50 μm, such as about 25 μm, although other width values or ranges are contemplated and may be used. In other embodiments, the openings 163 may have vertical sidewalls and a uniform width. In some embodiments, the openings 163 have a circular cross-sectional shape in a plan view, although other cross-sectional shapes may be used.

In FIG. 1L, a conductive layer 164 is formed in the openings 163 and on the top surface of the dielectric layer 162, in accordance with some embodiments. The conductive layer 164 may include conductive vias 166 and a conductive pattern 168 formed on the dielectric layer 162 and the conductive vias 166. The conductive vias 166 are formed in the openings 163 and in physical contact with the metal pads of the first conductive pattern 106. Since the openings 163 may have inclined sidewalls, the conductive vias 166 also have inclined sidewalls. The conductive pattern 168 may include both metal pads and metal traces for routing electrical signals, power, and/or ground lines, although in some embodiments the conductive pattern 168 may only include metal pads. In some embodiments, the metal pads of the conductive pattern 168 have a circular cross-sectional shape in a plan view, although other cross-sectional shapes may be used. The material and formation method of the conductive layer 164 may be similar to those of the conductive layers 114 and 138 described above, and thus are not repeated here.

Additional dielectric layers 170, 178 and their corresponding conductive layers 172, 180 (e.g., including conductive vias 174, 182 and conductive patterns 176, 184) may then be formed over the dielectric layer 162 and the conductive layer 164 using materials and techniques similar to those described above to form the second redistribution structure 160, in accordance with some embodiments.

FIG. 1L illustrates the second redistribution structure 160 as having three dielectric layers 162, 170, 178 and three conductive layers 164, 172, 180, but the second redistribution structure 160 may have any appropriate number of dielectric layers and conductive layers in different embodiments. If fewer dielectric layers and conductive layers are to be formed, some steps and processes discussed above may be omitted. If more dielectric layers and conductive layers are to be formed, steps and processes discussed above may be repeated. The thickness of the dielectric layers 162, 170, 178 of the second redistribution structure 160 may be the same or similar, or the dielectric layers may have a different thickness (for example, the dielectric layer (e.g., 178) closer to the outside (i.e., the upper side shown in FIG. 1L) may have a greater thickness). The thickness of the conductive layer 164, 172, 180 of the second redistribution structure 160 may be the same or similar, or the conductive layers may have a different thickness (for example, the conductive layer (e.g., 180) closer to the outside (i.e., the upper side shown in FIG. 1L) may have a greater thickness).

It should be noted that FIGS. 1K to 1L also illustrate the formation of metal patterns (or pads) 168P, 176P, 184P and metal vias 166P, 174P, 182P in and/or on the second redistribution structure 160 and adjacent the edge of the package (e.g., within the dashed box shown in FIG. 1L) in accordance with some embodiments. In some embodiments, the metal patterns 168P, 176P, 184P and metal vias 166P, 174P, 182P adjacent the edge of the package are formed using the same processes and materials used to form the corresponding conductive patterns 168, 176, 184 and conductive vias 166, 174, 182 located in the internal functional area of the package (e.g., those shown in the center of the figures and adjacent and/or over the first die 124 and encapsulant 130). For example, the metal patterns 168P, 176P, 184P and metal vias 166P, 174P, 182P may be formed simultaneously with the corresponding conductive patterns 168, 176, 184 and conductive vias 166, 174, 182 (the term “corresponding” as used here means that these components are located on the same level). In some embodiments, the metal patterns 168P, 176P, 184P and metal vias 166P, 174P, 182P are electrically isolated from the corresponding conductive patterns 168, 176, 184 and conductive vias 166, 174, 182. In some embodiments, the metal patterns 168P, 176P, 184P and metal vias 166P, 174P, 182P extend from the top surface of the second redistribution structure 160 to the bottom surface of the second redistribution structure 160 (to contact the bottom surface of the metal pattern 106P), and are arranged along the entire edge of the package in a plan view. As will be discussed in greater detail below, the metal patterns 168P, 176P, 184P and metal vias 166P, 174P, 182P may form (and be collectively referred to as) a third seal ring part SP3, which is also a part of a seal ring SR of the chip package 100 (see e.g., FIG. 1N).

In FIG. 1M, a solder resist layer 186 is formed on the outermost dielectric layer 178 and the outermost conductive pattern 184 (and the metal pattern 184P), and UBMs 188 are formed through the solder resist layer 186 and in physical contact with the exposed portions of the conductive pattern 184, and solder joints 190 are formed on the UBMs 188, in accordance with some embodiments. The solder joints 190 may be used to allow the resulting package (e.g., chip package 100) to be bonded to another component or system. Other conductive connectors may be used. The materials and formation methods of the solder resist layer 186, UBMs 188 and solder joints 190 may be similar to those of the solder resist layer 146, UBMs 148 and solder joints 152 described above, and thus are not repeated here. In some embodiments, the metal pattern 184P remains buried within the solder resist layer 186 (i.e., not exposed) after the UBMs 188 are formed.

Afterwards, a singulation process is performed to separate the resulting structure shown in FIG. 1M into individual chip packages 100, in accordance with some embodiments. The singulation process may include mechanical sawing, laser sawing, etching, dicing, a combination thereof, or the like. FIG. 1N illustrates a singulated chip package 100 including an IC die (e.g., second die 150) attached to a (reconstructed) redistribution layer (RDL) structure (e.g., including a core substrate 110, first die 124 and encapsulant 130 embedded in the core substrate 110, and first/top redistribution structure 140 and second/bottom redistribution structure 160 on both sides of the core substrate 110) in accordance with some embodiments. Although not shown, additional passive devices (e.g., surface mount components) may optionally be attached to the surface of the RDL structure to enable the chip package 100 to provide the desired functionality.

As shown in FIG. 1N, a first stack of metal pattern/pad layers (e.g., 106P, 118P, 132P) and metal vias (e.g., 116P, 120P) (also referred to as a first seal ring part SP1) is disposed in and penetrates the peripheral region of the core substrate 110. The first seal ring part SP1 is electrically isolated from the conductive features (e.g., conductive patterns 106, 118, 132 and conductive vias 116, 120) and the first die 124 disposed in the internal functional region of the core substrate 110. A second stack of metal pattern/pad layers (e.g., 144P) and metal vias (e.g., 142P) (also referred to as a second seal ring part SP2) is disposed in and penetrates the peripheral region of the first/top redistribution structure 140, and in physical contact with the first seal ring part SP1. The second seal ring part SP2 is electrically isolated from the conductive features (e.g., conductive pattern 144 and conductive vias 142) disposed in the internal functional region of the first/top redistribution structure 140. Also, a third stack of metal pattern/pad layers (e.g., 168P, 176P, 184P) and metal vias (e.g., 166P, 174P, 182P) (also referred to as a third seal ring part SP3) is disposed in and penetrates the peripheral region of the second/bottom redistribution structure 160, and in physical contact with the first seal ring part SP1. The third seal ring part SP3 is electrically isolated from the conductive features (e.g., conductive patterns 168, 176, 184 and conductive vias 166, 174, 182) disposed in the internal functional region of the first/top redistribution structure 140. As such, a seal ring structure SR, consisting of a stack of metal pattern/pad layers and metal vias, is formed at the edge of the chip package 100, and extends through the core substrate 100 from the top surface of the first/top redistribution structure 140 to the bottom surface of the second/bottom redistribution structure 160.

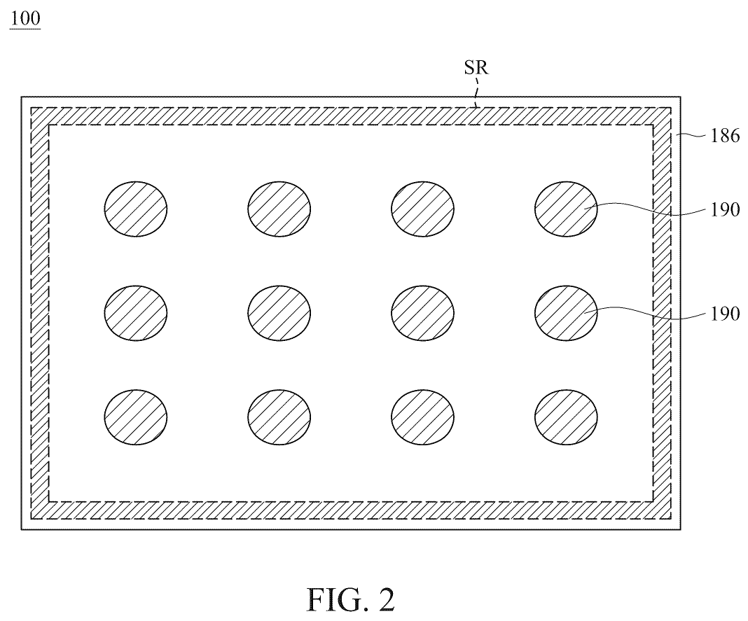

The seal ring structure SR defines a continuous wall or barrier that protects the IC dies and conductive features within the package (e.g., the seal ring structure SR extends continuously along the entire edge of the package in a plan view, as shown in FIG. 2). Due to the larger size of panel-level packaging, warpage and stress problems are more serious. These problems can be improved by providing the seal ring structure SR. For example, the seal ring structure SR can protect the IC dies and conductive features with the package during the singulation process (e.g., avoid delamination or crack propagation occurring in the RDL structure). Further, the seal ring structure SR can also prevent moisture from penetrating into the internal function region of the package. Accordingly, the reliability of the package structure is improved.

In some embodiments, the metal vias (e.g., 116P, 120P) embedded in the core substrate 110 have inclined sidewalls. For example, the width W11 of the metal vias (e.g., 116P, 120P) gradually decreases toward the second/bottom redistribution structure 160. In some embodiments, the metal vias (e.g., 142P) embedded in the first/top redistribution structure 140 have inclined sidewalls. For example, the width W12 of the metal vias (e.g., 142P) gradually decreases toward the core substrate 110. In some embodiments, the metal vias (e.g., 166P, 174P, 182P) embedded in the second/bottom redistribution structure 160 have inclined sidewalls. For example, the width W13 of the metal vias (e.g., 166P, 174P, 182P) gradually decreases toward the core substrate 110. In other words, the width W12 of the metal vias (e.g., 142P) gradually decreases toward the core substrate 110 along a first direction, while the width W13 of the metal vias (e.g., 166P, 174P, 182P) gradually decreases toward the core substrate 110 along a second direction opposite to the first direction.

In some embodiments, the width W11 of the metal vias (e.g., 116P, 120P) embedded in the core substrate 110 is greater than the width W12 of the metal vias (e.g., 142P) embedded in the first/top redistribution structure 140, and is greater than the width W13 of the metal vias (e.g., 166P, 174P, 182P) embedded in the second/bottom redistribution structure 160. This is due to the different hardness of different materials and the different via opening formation processes used. In some cases, the ratio W12/W11 (or the ratio W13/W11) may be in a range from about 0.1 to about 0.4, such as about 0.2, although other ratio values or ranges are contemplated and may be used. In some embodiments, the width W12 may be equal to, greater than or smaller than the width W13. For example, in some cases, the ratio W12/W13 may be in a range from about 0.8 to about 1.2, such as about 1.0, although other ratio values or ranges are contemplated and may be used.

In some embodiments, the metal vias (e.g., 142P) embedded in the first/top redistribution structure 140 and the metal vias (e.g., 116P, 120P) embedded in the core substrate 110 are vertically aligned. In some embodiments, some of the metal vias (e.g., 166P, 182P) embedded in the second/bottom redistribution structure 160 are vertical aligned with the metal vias (e.g., 116P, 120P) embedded in the core substrate 110, while some of the metal vias (e.g., 174P) are vertically offset from the metal vias (e.g., 116P, 120P). For example, as shown in FIG. 1N, the metal vias (e.g., 166P, 174P, 182P) embedded in the second/bottom redistribution structure 160 may be staggered vias, which may help avoid stress concentration and reduce the chance of damage to the seal ring structure SR. Other suitable configurations may be used.

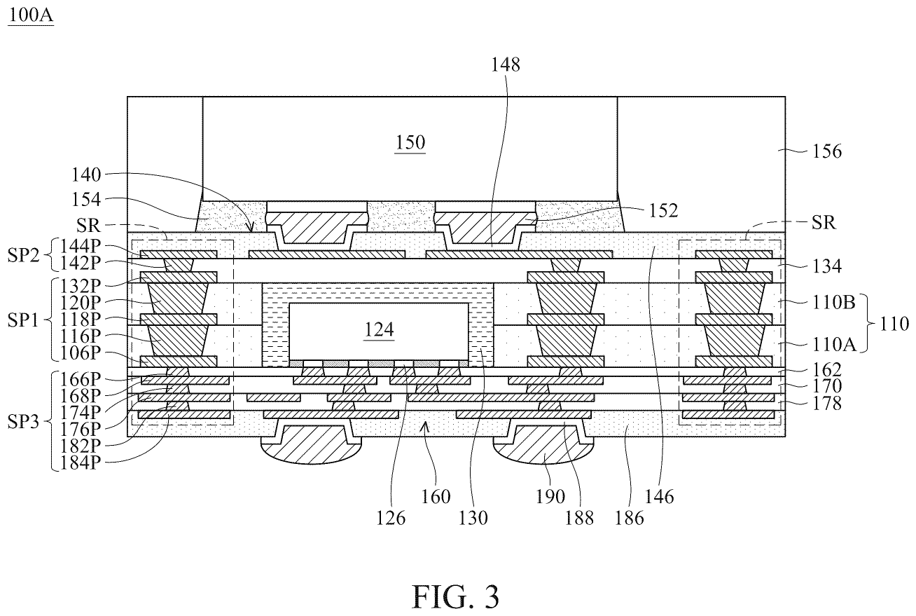

Many variations and/or modifications can be made to embodiments of the disclosure. Some variations of some embodiments are described below with reference to FIGS. 3 to 6.

FIG. 3 illustrates a cross-sectional view of a chip package 100A, in accordance with some embodiments. The chip package 100A is similar to the chip package 100 shown in FIG. 1N, except that all metal vias (e.g., 166P, 174P, 182P) of the seal ring structure SR embedded in the second/bottom redistribution structure 160 are vertical aligned with the metal vias (e.g., 116P, 120P) embedded in the core substrate 110. This configuration is suitable for cases where the RDL structure stress issue is less severe.

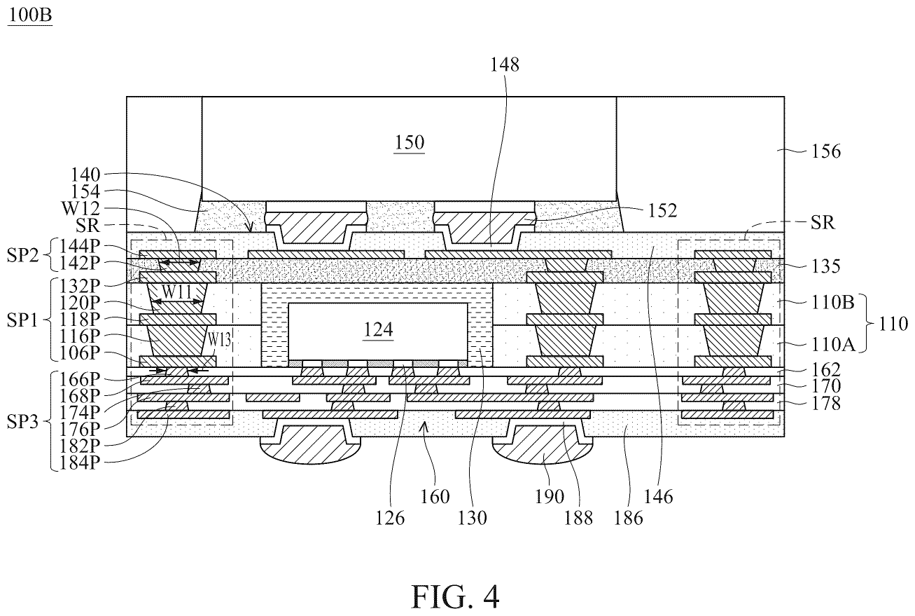

FIG. 4 illustrates a cross-sectional view of a chip package 100B, in accordance with some embodiments. The chip package 100B is similar to the chip package 100 shown in FIG. 1N, except that the dielectric layer 134 of the first/top redistribution structure 140 is replaced with a dielectric layer 135 made of one or more layers of Ajinomoto build-up film (ABF). Since the thickness and hardness of the ABF layer (i.e., dielectric layer 135) may be higher than those of the polymer layer (i.e., the dielectric layer 134), laser drilling is required to form openings in the dielectric layer 135 for the conductive vias 142 and the metal vias 142P of the seal ring structure SR. This results in the width W12 of the metal vias (e.g., 142P) embedded in the dielectric layer 135 of the first/top redistribution structure 140 becoming larger (but still smaller than the width W11 of the metal vias (e.g., 116P, 120P) embedded in the core substrate 110). In some cases where an ABF layer is used as the dielectric layer 135, the ratio W12/W13 may be in a range from about 2 to about 4 (i.e., the width W12 is at least twice the width W13), such as about 2.5, although other ratio values or ranges are contemplated and may be used.

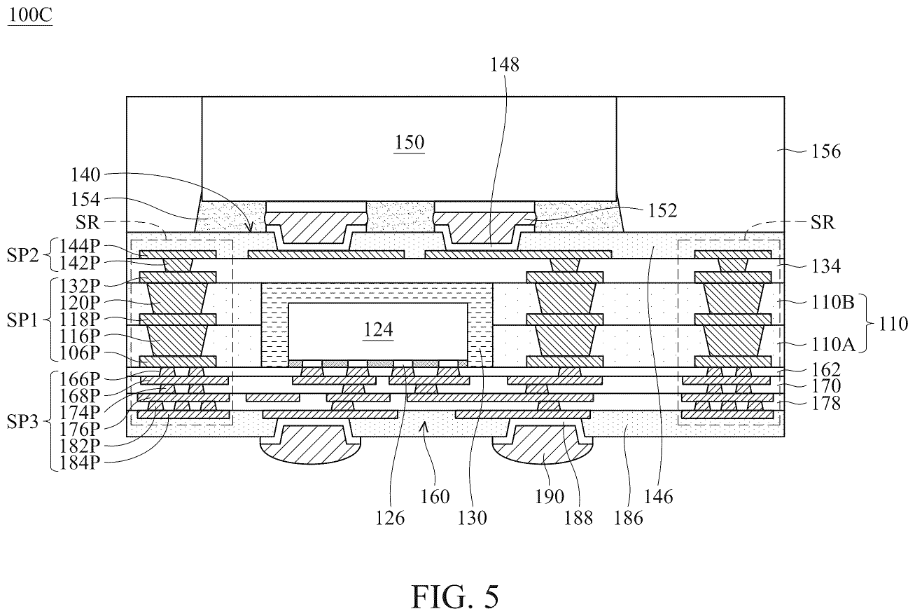

FIG. 5 illustrates a cross-sectional view of a chip package 100C, in accordance with some embodiments. The chip package 100C is similar to the chip package 100 shown in FIG. 1N, except that the number of metal vias (e.g., 166P, 174P, 182P) in each metal via layer of the seal ring structure SR embedded in the second/bottom redistribution structure 160 can be greater than 1. This increases the protective effect of the seal ring structure SR. Additionally or alternatively, the number (e.g., three) of the metal vias (e.g., 182P) in the outermost metal via layer of the seal ring structure SR may be larger than the number (e.g., two) of the metal vias (e.g., 166P, 174P) in other inner metal via layers to prevent the outermost metal via layer of the seal ring structure SR from being easily damaged by greater stress. Other quantities and configurations of the metal vias may be used.

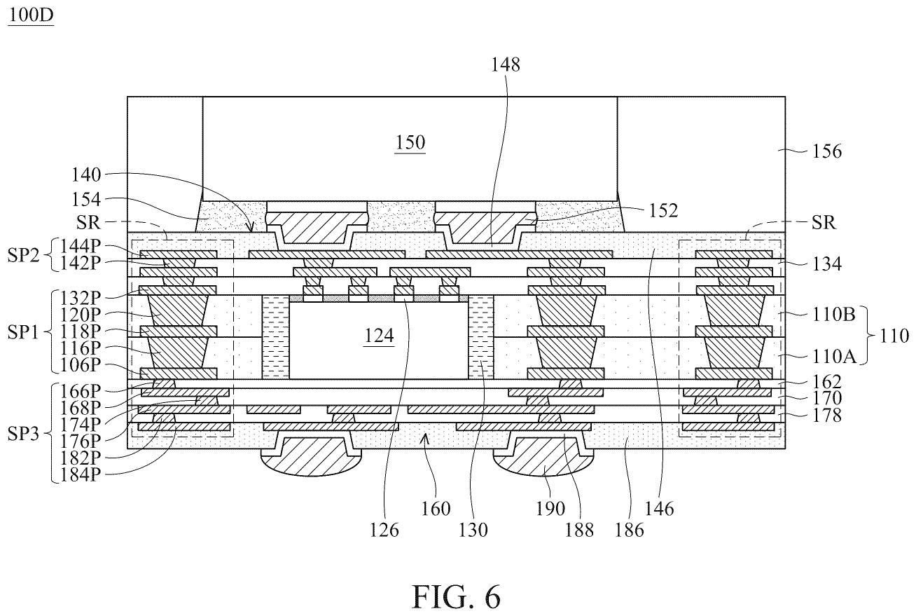

FIG. 6 illustrates a cross-sectional view of a chip package 100D, in accordance with some embodiments. The chip package 100D is similar to the chip package 100 shown in FIG. 1N, except that the active side of the first die 124 embedded in the core substrate 110 faces upward (i.e., toward the second die 150) and the die connectors 126 of the first die 124 are electrically and mechanically coupled to the conductive features within the first/top redistribution structure 140. This configuration may also reduce the signal transmitting routes between the first die 124 and the second die 150 for improved performance. The corresponding adjustments to the arrangement to the conductive features within the first/top redistribution structure 140 and second/bottom redistribution structure 160 may be referred to as shown in FIG. 6 are will not be described further here.

It should be understood that the structures, configurations and the manufacturing methods described herein are only illustrative, and are not intended to be, and should not be construed to be, limiting to the present disclosure. Many alternatives and modifications will be apparent to those skilled in the art, once informed by the present disclosure. For example, various features in the above-mentioned different embodiments can be combined arbitrarily. In addition, while the present disclosure is described using embodiments in which a single seal ring structure is provided in the RDL structure of the package, embodiments in which multiple seal ring structures may be provided in the RDL structure of the package are expressly contemplated herein. For example, an inner seal ring structure and an outer seal structure can be arranged concentrically.

In summary, the embodiments of the present disclosure have some advantageous features. By providing a seal ring structure at the edge of the panel-level chip package (e.g., in the peripheral regions of the core substrate and the redistribution structures on both sides thereof), the IC dies and conductive features with the package can be protected during the singulation process and/or moisture can be prevented from penetrating into the internal function region of the package. Accordingly, the reliability of the package structure is improved.

In accordance with some embodiments, a chip package structure is provided. The chip package structure includes a core substrate including a core material layer; an encapsulant embedded in the core material layer; an integrated circuit (IC) die embedded in the encapsulant; a first redistribution structure disposed above the core substrate, including a first dielectric layer and a first conductive layer in the first dielectric layer; a second redistribution structure disposed below the core substrate, including a second dielectric layer and a second conductive layer in the second dielectric layer; conductive features embedded in the core material layer and electrically connect the first redistribution structure and the second redistribution structure; a seal ring structure disposed in the peripheral regions of the core substrate, the first redistribution structure and the second redistribution structure, wherein the seal ring structure includes a stack of metal pattern layers and metal vias and is electrically isolated from the first conductive layer, the second conductive layer and the conductive features; and conductive connectors attached to the second redistribution structure.

In accordance with some embodiments, a chip package structure is provided. The chip package structure includes a core substrate; an encapsulant embedded in the core substrate; a first die embedded in the encapsulant; a first redistribution structure disposed above the core substrate, including a first dielectric layer and a first conductive layer in the first dielectric layer; a second redistribution structure disposed below the core substrate, including a second dielectric layer and a second conductive layer in the second dielectric layer; conductive features embedded in the core substrate and electrically connect the first redistribution structure and the second redistribution structure; a seal ring structure disposed at the edge of the chip package structure, including: a first stack of metal pattern layers and metal vias disposed in the core substrate and electrically isolated from the conductive features; a second stack of metal pattern layers and metal vias disposed in the first dielectric layer and electrically isolated from the first conductive layer; and a third stack of metal pattern layers and metal vias disposed in the second dielectric layer and electrically isolated from the second conductive layer, wherein the first stack, the second stack and the third stack are connected to each other, wherein wherein the width of a metal via of the first stack is greater than the width of a metal via of the second stack and greater than the width of a metal via of the third stack; and conductive connectors attached to the second redistribution structure.

In accordance with some embodiments, a method of forming a chip package structure is provided. The method includes forming conductive features in a core material layer of a core substrate; forming a first stack of metal pattern layers and metal vias in the peripheral region of the core material layer and electrically isolated from the conductive features; forming a cavity in the core material layer, and placing an integrated circuit (IC) die in the cavity; filling the cavity with an encapsulant to encapsulate the IC die; forming a first distribution structure, including a first dielectric layer and a first conductive layer in the first dielectric layer, above the core substrate; forming a second stack of metal pattern layers and metal vias in the peripheral region of the first dielectric layer and electrically isolated from the first conductive layer; forming a second distribution structure, including a second dielectric layer and a second conductive layer in the second dielectric layer, below the core substrate, wherein the first conductive layer and the second conductive layer are electrically connected through the conductive features; forming a third stack of metal pattern layers and metal vias in the peripheral region of the second dielectric layer and electrically isolated from the second conductive layer, wherein the first stack, the second stack and the third stack are connected to each other to form a seal ring structure; and attaching conductive connectors to the second distribution structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip package structure, comprising:
a core substrate comprising a core material layer;
an encapsulant embedded in the core material layer;
an integrated circuit (IC) die embedded in the encapsulant;
a first redistribution structure disposed above the core substrate, comprising a first dielectric layer and a first conductive layer in the first dielectric layer;
a second redistribution structure disposed below the core substrate, comprising a second dielectric layer and a second conductive layer in the second dielectric layer;
conductive features embedded in the core material layer and electrically connect the first redistribution structure and the second redistribution structure;
a seal ring structure disposed in peripheral regions of the core substrate, the first redistribution structure and the second redistribution structure, wherein the seal ring structure comprises a stack of metal pattern layers and metal vias and is electrically isolated from the first conductive layer, the second conductive layer and the conductive features; and
conductive connectors attached to the second redistribution structure.

2. The chip package structure as claimed in claim 1, wherein the seal ring structure extends through the core substrate from a top surface of the first redistribution structure to a bottom surface of the second redistribution structure.

3. The chip package structure as claimed in claim 1, wherein the seal ring structure extends continuously along the entire edge of the chip package structure in a plan view.

4. The chip package structure as claimed in claim 1, wherein the seal ring structure comprises:
a first stack of metal pattern layers and metal vias disposed in the core material layer at the same level as the conductive features;
a second stack of metal pattern layers and metal vias disposed in the first dielectric layer at the same level as the first conductive layer; and
a third stack of metal pattern layers and metal vias disposed in the second dielectric layer at the same level as the second conductive layer.

5. The chip package structure as claimed in claim 4, wherein a width of a metal via of the first stack is greater than a width of a metal via of the second stack and greater than a width of a metal via of the third stack.

6. The chip package structure as claimed in claim 5, wherein the width of the metal via of the second stack is at least twice the width of the metal via of the third stack.

7. The chip package structure as claimed in claim 4, wherein:
the width of the metal via of the second stack gradually decreases toward the core substrate along a first direction; and
the width of the metal via of the third stack gradually decreases toward the core substrate along a second direction opposite to the first direction.

8. The chip package structure as claimed in claim 4, wherein the third stack comprises vertically aligned or staggered metal vias.

9. The chip package structure as claimed in claim 4, wherein the third stack comprises a plurality of metal via layers, and a number of metal vias in one of the metal via layers is greater than 1.

10. The chip package structure as claimed in claim 9, wherein a number of metal vias in an outer one of the metal via layers is greater than a number of metal vias in an inner one of the metal via layers.

11. The chip package structure as claimed in claim 1, wherein the IC die comprises die connectors electrically connected to one of the first conductive layer and the second conductive layer.

12. A chip package structure, comprising:
a core substrate;
an encapsulant embedded in the core substrate;
a first die embedded in the encapsulant;
a first redistribution structure disposed above the core substrate, comprising a first dielectric layer and a first conductive layer in the first dielectric layer;
a second redistribution structure disposed below the core substrate, comprising a second dielectric layer and a second conductive layer in the second dielectric layer;
conductive features embedded in the core substrate and electrically connect the first redistribution structure and the second redistribution structure;
a seal ring structure disposed at an edge of the chip package structure, comprising:
a first stack of metal pattern layers and metal vias disposed in the core substrate and electrically isolated from the conductive features;
a second stack of metal pattern layers and metal vias disposed in the first dielectric layer and electrically isolated from the first conductive layer; and
a third stack of metal pattern layers and metal vias disposed in the second dielectric layer and electrically isolated from the second conductive layer,
wherein the first stack, the second stack and the third stack are connected to each other,
wherein a width of a metal via of the first stack is greater than a width of a metal via of the second stack and greater than a width of a metal via of the third stack; and
conductive connectors attached to the second redistribution structure.

13. The chip package structure as claimed in claim 12, wherein top surfaces of the encapsulant and the core substrate are coplanar, and bottom surfaces of the encapsulant and the core substrate are coplanar.

14. The chip package structure as claimed in claim 12, further comprising:
a first solder resist layer covering a top surface of the first redistribution structure; and
a second solder resist layer covering a bottom surface of the second redistribution structure,
wherein the second stack comprises an outermost metal pattern layer embedded in the first solder resist layer, and the third stack comprises an outermost metal pattern layer embedded in the second solder resist layer.

15. The chip package structure as claimed in claim 14, further comprising:
a second die attached to a portion of the first conductive layer exposed through the first solder resist layer.

16. A method of forming a chip package structure, comprising:
forming conductive features in a core material layer of a core substrate;
forming a first stack of metal pattern layers and metal vias in a peripheral region of the core material layer and electrically isolated from the conductive features;
forming a cavity in the core material layer, and placing an integrated circuit (IC) die in the cavity;
filling the cavity with an encapsulant to encapsulate the IC die;
forming a first distribution structure, comprising a first dielectric layer and a first conductive layer in the first dielectric layer, above the core substrate;
forming a second stack of metal pattern layers and metal vias in a peripheral region of the first dielectric layer and electrically isolated from the first conductive layer;
forming a second distribution structure, comprising a second dielectric layer and a second conductive layer in the second dielectric layer, below the core substrate, wherein the first conductive layer and the second conductive layer are electrically connected through the conductive features;
forming a third stack of metal pattern layers and metal vias in a peripheral region of the second dielectric layer and electrically isolated from the second conductive layer, wherein the first stack, the second stack and the third stack are connected to each other to form a seal ring structure; and
attaching conductive connectors to the second distribution structure.

17. The method as claimed in claim 16, wherein:
the first stack of metal pattern layers and metal vias are formed simultaneously with the conductive features;
the second stack of metal pattern layers and metal vias are formed simultaneously with the first conductive layer; and
the third stack of metal pattern layers and metal vias are formed simultaneously with the second conductive layer.

18. The method as claimed in claim 16, wherein:
the first stack of metal pattern layers and metal vias are formed using the same materials used to form the conductive features;
the second stack of metal pattern layers and metal vias are formed using the same materials used to form the first conductive layer; and
the third stack of metal pattern layers and metal vias are formed using the same materials used to form the second conductive layer.

19. The method as claimed in claim 16, wherein the seal ring structure has a rectangular frame shape in a plan view.

20. The method as claimed in claim 16, wherein forming the conductive features comprises:
forming an opening in the core material layer by laser drilling; and
forming a conductive material in the opening and/or on the core material layer to form the conductive features.
